(19) United States
(12) Patent Application Publication
(10) Pub. No.: US 2025/0380443 A1
(43) Pub. Date: Dec. 11, 2025

(54) SEMICONDUCTOR DEVICE

(71) Applicant: WIN SEMICONDUCTORS CORP., TAOYUAN CITY (TW)

(72) Inventors: Li-Cheng CHANG, TAOYUAN CITY (TW); Jung-Tao CHUNG, TAOYUAN CITY (TW); Yu-Chia CHEN, TAOYUAN CITY (TW); Wei-Hao LEE, TAOYUAN CITY (TW); Lung-Yi TSENG, TAOYUAN CITY (TW)

(21) Appl. No.: 18/739,663

(22) Filed: Jun. 11, 2024

(51) Int. Cl. H01L 29/778; H01L 21/285; H01L 23/31; H01L 29/205; H01L 29/417; H01L 29/423; H01L 29/66

(52) U.S. Cl. CPC H10D 30/475; H01L 21/28581; H01L 21/28593; H01L 23/3171; H10D 30/015; H10D 62/824; H10D 64/258; H10D 64/411

(57) ABSTRACT

A semiconductor structure includes a substrate, a semiconductor stack, a cap layer, a source electrode, a drain electrode, and a gate. The semiconductor stack is disposed on the substrate. The cap layer is disposed on the semiconductor stack. The cap layer includes an intrinsic cap layer, an etch-stop layer, and an n-type cap layer. There is an opening through the cap layer. The source electrode and the drain electrode are disposed on the semiconductor stack. The gate is disposed in the opening and between the source electrode and the drain electrode. The first distance between the gate and a first portion of the n-type cap layer adjacent to the drain electrode is greater than the second distance between the gate and a second portion of the n-type cap layer adjacent to the source electrode.

### BACKGROUND OF THE INVENTION

### Field of the Invention

The present disclosure relates to a HEMT (high electron mobility transistor) structure, and more particularly to a HEMT structure with an asymmetric recess structure.

### Description of the Related Art

HEMT structures are widely used in high-frequency and high-power semiconductor devices due to their high mobility, high breakdown voltage and high output voltage.

These HEMT structures may have a stack of different III-V semiconductor layers, and heterojunctions may be formed at their interfaces. Due to the band bending at the heterojunctions, a potential well may be formed at the bending conduction band so that a two-dimensional electron gas (2DEG) or a two-dimensional hole gas (2DHG) is formed in the potential well.

Although existing HEMT structures have generally been adequate for their intended purposes, they have not been entirely satisfactory in all respects, and need to be improved.

### BRIEF SUMMARY OF THE INVENTION

An embodiment of the present disclosure provides a semiconductor structure including a substrate, a semiconductor stack, a cap layer, a source electrode, a drain electrode, and a gate. The semiconductor stack is disposed on the substrate. The cap layer is disposed on the semiconductor stack. The cap layer includes an intrinsic cap layer, an etch-stop layer, and an n-type cap layer. There is an opening through the cap layer. The source electrode and the drain electrode are disposed on the semiconductor stack. The gate is disposed in the opening and between the source electrode and the drain electrode. The first distance between the gate and a first portion of the n-type cap layer adjacent to the drain electrode is greater than the second distance between the gate and a second portion of the n-type cap layer adjacent to the source electrode.

An embodiment of the present disclosure provides a semiconductor device including a substrate, a semiconductor stack, a cap layer, a source electrode and a drain electrode, and a gate. The semiconductor stack is disposed on the substrate. The cap layer is disposed on the semiconductor stack and having a top opening and a bottom opening. The bottom opening overlaps the top opening. The source electrode and the drain electrode are disposed on the semiconductor stack. The gate is disposed in the top opening and the bottom opening, between the source electrode and the drain electrode, and spaced apart from the cap layer. The first distance between the gate and the cap layer on the drain-side in the top opening is greater than the second distance between the gate and the cap layer on a source-side in the top opening, and the third distance between the gate and the cap layer on the drain-side in the bottom opening is substantially equal to the fourth distance between the gate and the cap layer on the source-side in the bottom opening.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1E are cross-sectional representations of various stages of forming a semiconductor structure in accordance with some embodiments.

FIG. 2 is a cross-sectional representation of a semiconductor structure in accordance with some embodiments.

FIG. 3 is a cross-sectional representation of a semiconductor structure in accordance with some embodiments.

FIG. 4 is a cross-sectional representation of a semiconductor structure in accordance with some embodiments.

FIG. 5 is a cross-sectional representation of a semiconductor structure in accordance with some embodiments.

### DETAILED DESCRIPTION OF THE INVENTION

The following disclosure provides many different embodiments, or examples, for implementing different features of the disclosure. Specific examples of components and arrangements are described below to simplify the present disclosure. These are, of course, merely examples and are not intended to be limiting. For example, the formation or the disposal of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Herein, the terms “around,” “about,” “substantial” usually mean within 20% of a given value or range, such as within 10%, 5%, 3%, 2%, 1%, or 0.5%. It should be noted that the quantity herein is a substantial quantity, which means that the meaning of “around,” “about,” “substantial” are still implied even without specific mention of the terms “around,” “about,” “substantial.”

Although some embodiments are discussed with operations performed in a particular order, these operations may be performed in another logical order. In different embodiments, additional operations can be provided before, during, and/or after the stages described the present disclosure. Some of the stages that are described can be replaced or eliminated for different embodiments. Additional features can be added to the semiconductor structure in the present disclosure. Some of the features described below can be replaced or eliminated for different embodiments.

The present disclosure provides a HEMT structure. The HEMT structure may include epitaxial tri-layer cap layers, but not limited thereto. There may be two recesses formed in the tri-layer cap layers. With an asymmetric top recess and a symmetric bottom recess, the capacitance may be reduced, and the device performance may be enhanced. With the protection layer of the epitaxial tri-layer cap layers, the surface traps may be reduced.

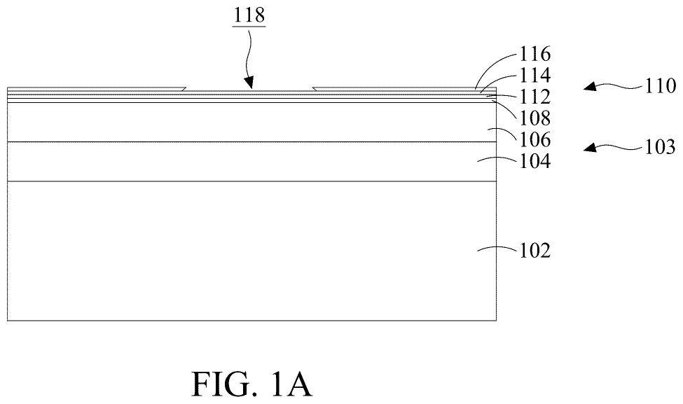

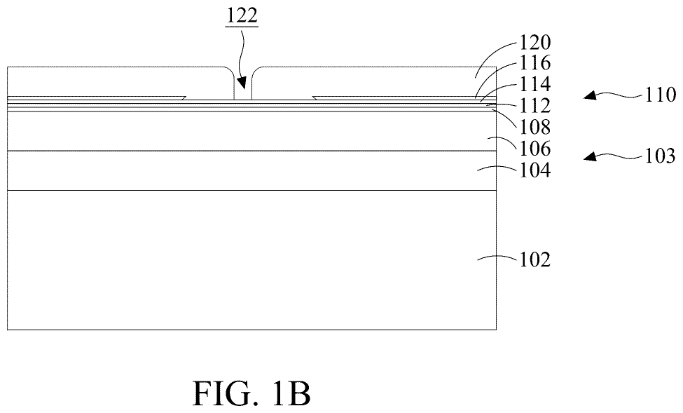

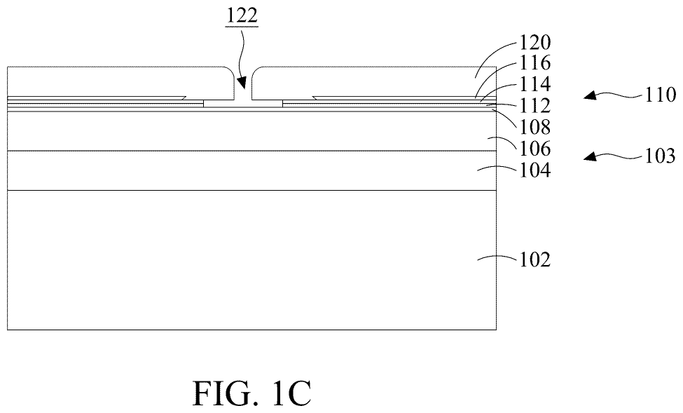

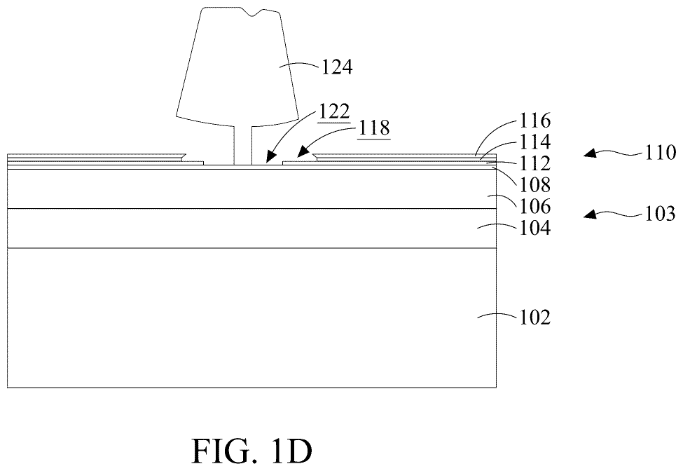

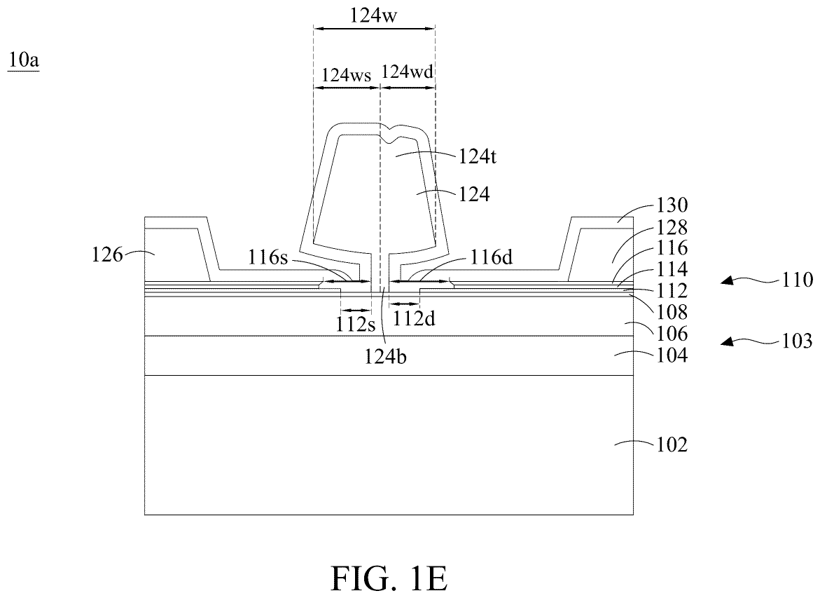

FIGS. 1A-1E are cross-sectional representations of various stages of forming a semiconductor structure 10a in accordance with some embodiments.

A substrate 102 is provided, as shown in FIG. 1A in accordance with some embodiments. The substrate 102 may be a semiconductor substrate, a glass substrate, a ceramic substrate, a sapphire substrate, semiconductor-on-insulator (SOI) substrate, or a combination thereof, but not limited thereto. The substrate 102 may include III-V semiconductors such as GaN, AlGaN, AlN, GaAs, AlGaAs, InP, InAlAs, InGaAs, or a combination thereof, but not limited thereto, the substrate 102 may include IV semiconductor, such as Si or Ge. The substrate 102 may include undoped or doped material, such as undoped GaAs, but not limited thereto.

Next, a semiconductor stack 103 may be formed on the substrate 102, as shown in FIG. 1A in accordance with some embodiments. The semiconductor stack 103 may include epitaxial layers, such as a buffer layer 104, a channel layer 106, and a carrier supply layer 108, as shown in FIG. 1A in accordance with some embodiments. The buffer layer 104 may be formed on the substrate 102, and the channel layer 106 may be formed on the buffer layer 104. The carrier supply layer 108 may be formed on the channel layer 106. The carrier supply layer 108 may be a single layer or a multi-layer structure. The carrier supply layer 108 may have a bandgap wider than that of the channel layer 106. In some embodiments, the substrate 102 includes GaAs, and the buffer layer 104 includes at least one of GaAs and AlGaAs. In some embodiments, the channel layer 106 includes at least one of GaAs and InGaAs, and the carrier supply layer 108 includes at least one of AlGaAs, AlGaAsP and InAlGaAs, InGaP, InGaPAs, AlInGaP, or a combination thereof, but not limited thereto. The buffer layer 104, the channel layer 106, and the carrier supply layer 108 may be formed by molecular-beam epitaxy (MBE), metalorganic chemical vapor deposition (MOCVD), hydride vapor phase epitaxy (HVPE), other suitable methods, or a combination thereof.

Since the channel layer 106 and the carrier supply layer 108 may be formed of different materials, their band gaps may be different. A heterojunction may be formed at the interface between the channel layer 106 and the carrier supply layer 108. The energy band may bend at the heterojunction, and a quantum well may be formed at the deep portion of the conduction band. The electrons provided by the carrier supply layer may be confined in the quantum well. Therefore, a two-dimensional electron gas (2DEG) may be formed at the interface between the channel layer 106 and the carrier supply layer 108, and a conducting current may be formed by the 2DEG.

Next, a cap layer 110 may be formed over the semiconductor stack 103, as shown in FIG. 1A in accordance with some embodiments. In some embodiments, the cap layer 110 may include a protection layer 112, an etch-stop layer 114, and/or a top cap layer 116. In some embodiments, the protection layer 112 is formed over the carrier supply layer 108, the etch-stop layer 114 is formed over the protection layer 112, and the top cap layer 116 is formed over the etch-stop layer 114, but not limited thereto.

In some embodiments, the protection layer 112 may include un-doped or lightly doped GaAs. The protection layer 112 may also be referred as the intrinsic cap layer 112. In some embodiments, the etch-stop layer 114 may include n-type doped AlAs. In some embodiments, the top cap layer 116 may include n-type doped GaAs. The top cap layer 116 may also be referred as the n-type cap layer 116. The protection layer 112, the etch-stop layer 114, and the top cap layer 116 may be formed by MBE, MOCVD, HVPE, other suitable methods, or a combination thereof.

In some embodiments, the doping concentration of the protection layer 112 may be less than 10¹⁸ cm⁻³, such as 10¹⁵ cm⁻³, 10¹⁶ cm⁻³ or 10¹⁷ cm⁻³. With lower concentration or intrinsic protection layer 112, the depletion region between the gate structure to the drain structure may be extended.

In some embodiments, the thickness of the protection layer 112 is in a range of about 5 angstrom to about 100 angstrom (5 Å≤thickness≤100 Å), such as 10 Å, 20 Å, 30 Å, 50 Å or 70 Å. In some embodiments, the thickness of the etch-stop layer 114 is in a range of about 5 angstrom to about 100 angstrom (5 Å≤thickness≤100 Å), such as 10 Å, 20 Å, 30 Å, 50 Å or 70 Å. In some embodiments, the thickness of the top cap layer 116 is in a range of about 100 angstrom to about 1000 angstrom (100 Å≤thickness≤1000 Å), such as 150 Å, 200 Å, 300 Å, 500 Å or 700 Å. In some embodiments, the ratio of the thickness of the protection layer 112 to the thickness of the top cap layer 116 is in a range of about 1 to 20 (1≤ratio≤20), such as 2, 5, 8, 10 or 12, but not limited thereto.

Next, an opening 118 may be formed in the top cap layer 116, and the top surface of the etch-stop layer 114 is exposed in the opening 118, as shown in FIG. 1A in accordance with some embodiments. The top cap layer 116 may be patterned by a patterning process. The patterning process may include a photolithography process and etching process. Examples of photolithography processes include photoresist coating, soft baking, mask aligning, exposure, post-exposure baking, developing the photoresist, rinsing and drying. The etching process may include a dry etching process, a wet etching process, or a combination thereof.

In some embodiments, the top surface of the top cap layer 116 may be wider than the bottom surface of the top cap layer 116 after the opening 118 is formed. The opening 118 may be gradually widened downwards, but not limited thereto, the opening 118 may be gradually widened upwards in accordance with other embodiments.

Next, a photoresist layer 120 may be formed over the cap layer 110, and an opening 122 may be formed in the photoresist layer 120, as shown in FIG. 1B in accordance with some embodiments. In some embodiments, the opening 122 is formed through the opening 118, and the top surface of the etch-stop layer 114 is exposed in the opening 122. In some embodiments, the opening 122 may be asymmetric corresponding to the top cap layer 116, that is, distances between the opening 122 and the top cap layer 116 may be not equal, or the opening 122 may not be disposed at the center of the opening 118.

Afterwards, part of the etch-stop layer 114 may be removed from the opening 122, and the protection layer 112 may be also removed from the opening 122, as shown in FIG. 1C in accordance with some embodiments. In some embodiments, the etch-stop layer 114 and the protection layer 112 may be laterally recessed. Therefore, the opening 122 may extend under the photoresist layer 120, but not limited thereto. In some embodiments, the etch-stop layer 114 and the protection layer 112 may be symmetrically removed, but not limited thereto. In some embodiments, the sidewalls of the etch-stop layer 114 and the protection layer 112 may be substantially aligned. The etch-stop layer 114 and the protection layer 112 may be removed by a dry etching process (e.g., reactive ion etching (RIE), an anisotropic plasma etching method), a wet etching process, or a combination thereof.

In some embodiments, the width of the opening 122 through the protection layer 112 is narrower than the width of the opening 118 through the top cap layer 116.

Next, a gate electrode 124 may be formed though the cap layer 110, as shown in FIG. 1D in accordance with some embodiments. The gate electrode 124 may include molybdenum (Mo), tungsten (W), tungsten-silicide (WSi), titanium (Ti), tungsten-titanium (TiW), iridium (Ir), palladium (Pd), platinum (Pt), gold (Ag), nickel (Ni), cobalt (Co), chromium (Cr), ruthenium (Ru), osmium (Os), rhodium (Rh), tantalum (Ta), tantalum nitride (TaN), aluminum (Al), rhenium (Re), other applicable conductive materials, or a combination thereof. The gate electrode 124 may be formed by a physical vapor deposition (PVD) process (such as resistive heating evaporation, e-beam evaporation, or sputtering), a chemical vapor deposition (CVD) process (such as a low pressure chemical vapor deposition process or a plasma enhanced chemical vapor deposition process), electroplating, atomic layer deposition (ALD), other suitable process, or a combination thereof. In some embodiments, the gate electrode 124 is formed by an evaporation process.

Later, the photoresist layer 120 is removed, and then the exposed etch-stop layer 114 is also removed, as shown in FIG. 1D in accordance with some embodiments. In some embodiments, part of the top surface of the protection layer 112 may be exposed. The photoresist layer 120 and the etch-stop layer 114 may be removed in an ashing process, one or more other applicable processes, or a combination thereof.

Next, a source electrode 126 and a drain electrode 128 may be formed over the semiconductor stack 103, as shown in FIG. 1E in accordance with some embodiments. For example, the source electrode 126 and the drain electrode 128 may be disposed on the top cap layer 116. The source electrode 126 and the drain electrode 128 may respectively include Ti, Al, W, Au, Pd, Au, Ge, Ni, Mo, Pt, other applicable metals, their alloys, or a combination thereof. The source electrode 126 and the drain electrode 128 may be formed by a PVD process (such as resistive heating evaporation, e-beam evaporation, or sputtering), a CVD process (such as a low pressure chemical vapor deposition process or a plasma enhanced chemical vapor deposition process), electroplating, ALD, other suitable process, or a combination thereof. In some embodiments, the source electrode 126 and the drain electrode 128 are formed by an evaporation process.

Next, a passivation layer 130 is formed over the substrate 102, as shown in FIG. 1E in accordance with some embodiments. In some embodiments, the passivation layer 130 may be formed over the gate electrode 124 and in the opening 122. The passivation layer 130 may provide an effective environmental barrier that protects the devices from moisture.

The passivation layer 130 may include silicon nitride, aluminum oxide, silicon oxide, silicon oxynitride, aluminum nitride, hafnium oxide, one or more other suitable passivation materials, or a combination thereof. In some embodiments, the passivation layer 130 includes silicon nitride. The passivation layer 130 may include a single layer or a multi-layered structure. The passivation layer 130 may be formed by atomic layer deposition (ALD), physical vapor deposition (PVD), chemical vapor deposition (CVD), or other suitable methods.

Since the opening 122 may be asymmetric according to the top cap layer 116, the distance 116d between the gate electrode 124 and the top cap layer 116 near the drain electrode 128 may be greater than the distance 116s between the gate electrode 124 and the top cap layer 116 near the source electrode 126 (116d>116s). Longer distance 116d between the gate electrode 124 to the top cap layer 116 near the drain electrode 128 may lower the capacitance, and device performance may be enhanced. In some embodiments, the distance 116d may be defined as the minimum distance between the bottom portion 124b of the gate electrode 124 and the top cap layer 116 near the drain electrode. The distance 116s may be defined as the minimum distance between the bottom portion 124b of the gate electrode 124 and the top cap layer 116 near the source electrode.

In some embodiments, the ratio of the distance 116d to the distance 116s (116d/116s) may be in a range of about 1.2 to about 8, such as 2, 3, 4 or 5. In some embodiments, the ratio of the distance 116d to the width 124w of the gate electrode 124 (116d/124w) may be in a range of about 0.05 to about 4, such as 0.1, 0.5, 1, 2 or 3. In some embodiments, the ratio of the distance 116s to the width 124w of the gate electrode 124 (116s/124w) may be in a range of about 0.05 to about 1.5, such as 0.1, 0.5, or 1. The width 124w of the gate electrode 124 may be defined as the maximum width of the top portion 124t of the gate electrode 124.

In some embodiments, the distance between the gate electrode 124 and the drain electrode 128 is greater than the distance between the gate electrode 124 and the source electrode 126.

The gate electrode 124 may include a bottom portion 124b and a top portion 124t. In some embodiments, the top portion 124t of the gate electrode 124 is asymmetric or symmetric according to the bottom portion 124b of the gate electrode 124. The top portion 124t may be the enlarged portion of the gate electrode 124, but not limited thereto. In some embodiments, a vertical auxiliary line may be defined from the center of the bottom portion 124b of the gate electrode 124. The distance 124ws may be defined as the maximum distance between the vertical auxiliary line and the sidewall of the top portion 124t of the gate electrode 124 adjacent to the source electrode 126. The distance 124wd may be defined as the maximum distance between the vertical auxiliary line and the sidewall of the top portion 124t of the gate electrode 124 adjacent to the drain electrode 128. The distance 124ws may be greater than the distance 124wd (124ws>124wd). In other embodiments, the distance 124ws may be substantially equal to or less than the distance 124wd (124ws≤ 124wd).

In some embodiments, the projection of the top cap layer 116 adjacent to the source electrode 126 may overlap a projection of the gate electrode 124 in a top view, and the projection of top cap layer 116 adjacent to the drain electrode 128 may be separated from the projection of the gate electrode 124 in a top view. In other embodiments, the projection of the top cap layer 116 adjacent to the source electrode 126 may be separated from the projection of the gate electrode 124 in a top view, and the projection of top cap layer 116 adjacent to the drain electrode 128 may be separated from the projection of the gate electrode 124 in a top view.

In some embodiments, the projection of the gate electrode 124 may cover the bottom opening 122 formed in the protection layer 112 in a top view.

Since the etch-stop layer 114 and the protection layer 112 may be symmetrically removed from the opening 122, the distance 112s between the gate electrode 124 to the protection layer 112 near the drain electrode 128 may be substantially equal to the distance 112d between the gate electrode 124 to the protection layer 112 near the source electrode 126. The protection layer 112 may reduce surface traps on the carrier supply layer 108. With shorter distances 112s and 112d between the gate electrode 124 and the protection layer 112, the surface traps may be reduced. In some other embodiments, the distance 112s between the gate electrode 124 to the protection layer 112 near the drain electrode 128 and the distance 112d between the gate electrode 124 to the protection layer 112 near the source electrode 126 may be different.

With a HEMT structure 10a having a tri-layered cap layer 110, greater distance 116d between the gate electrode 124 to the top cap layer 116 near the drain electrode 128 may reduce the capacitance, and the device performance may be enhanced. With substantially symmetric and/or short distances 112s and 112d between the gate electrode 124 to the protection layer 112, the surface traps may be reduced.

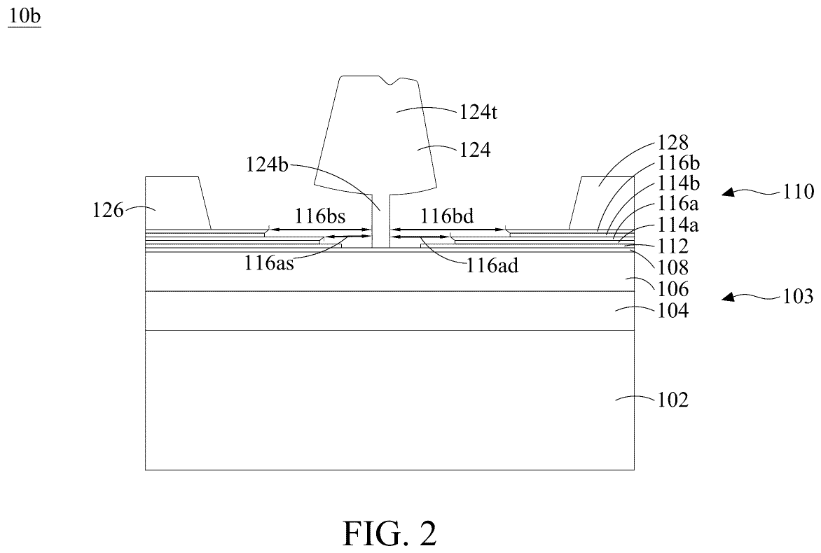

Many variations and/or modifications may be made to the embodiments of the disclosure. FIG. 2 is a cross-sectional representation of a semiconductor structure 10b in accordance with some embodiments. Some processes or devices are the same as, or similar to, those described in the embodiments above, and therefore the descriptions of these processes and devices are not repeated herein. The difference from the embodiments described above is that, as shown in FIG. 2 in accordance with some other embodiments, multiple etch-stop layers 114a and 114b and multiple top cap layers 116a and 116b may be formed over the protection layer 112.

In some embodiments, the cap layer 110 may include a protection layer 112, an etch-stop layer 114a, a top cap layer 116a, a second etch-stop layer 114b, and a second top cap layer 116b. In some embodiments, the protection layer 112 may be formed over the carrier supply layer 108, the etch-stop layer 114a may be formed over the protection layer 112, and the top cap layer 116a may be formed over the etch-stop layer 114a. In some embodiments, the second etch-stop layer 114b may be formed over the top cap layer 116a, and the second top cap layer 116b may be formed over the second etch-stop layer 114b. Processes used to form the second etch-stop layer 114b and the second top cap layer 116b may be similar to, or the same as, those used to form the etch-stop layer 114 and the top cap layer 116 described previously, and are not repeated herein for brevity.

In some embodiments, the protection layer 112 and the etch-stop layer 114a may be omitted. That is, the top cap layer 116a is disposed over the carrier supply layer 108, the second etch-stop layer 114b is disposed over the top cap layer 116a, and the second top cap layer 116b is disposed over the second etch-stop layer 114b, but not limited thereto.

The opening formed in the second etch-stop layer 114b and the second top cap layer 116b and the opening formed in the etch-stop layer 114a and the top cap layer 116a may be defined by different masks. The opening formed in the second etch-stop layer 114b and the second top cap layer 116b may be wider than the opening formed in the etch-stop layer 114a and the top cap layer 116a. Multiple top cap layers 116a and 116b may increase the breakdown voltage of the HEMT structure 10b.

The distance 116bd between the gate electrode 124 and the second top cap layer 116b near the drain electrode 128 may be greater than the distance 116bs between the gate electrode 124 to the second top cap layer 116b near the source electrode 126 (116bd>116bs). The distance 116ad between the gate electrode 124 and the top cap layer 116a near the drain electrode 128 may be greater than the distance 116as between the gate electrode 124 to the top cap layer 116a near the source electrode 126 (116ad>116as). The distances 116bd, 116bs, 116ad and 116as may be defined as the minimum distances between the corresponding top cap layer and the bottom portion 124b of the gate electrode 124. Longer distances 116bd and 116ad between the gate electrode 124 and the second top cap layer 116b and top cap layer 116a near the drain electrode 128 may lower the capacitance, and device performance may be enhanced.

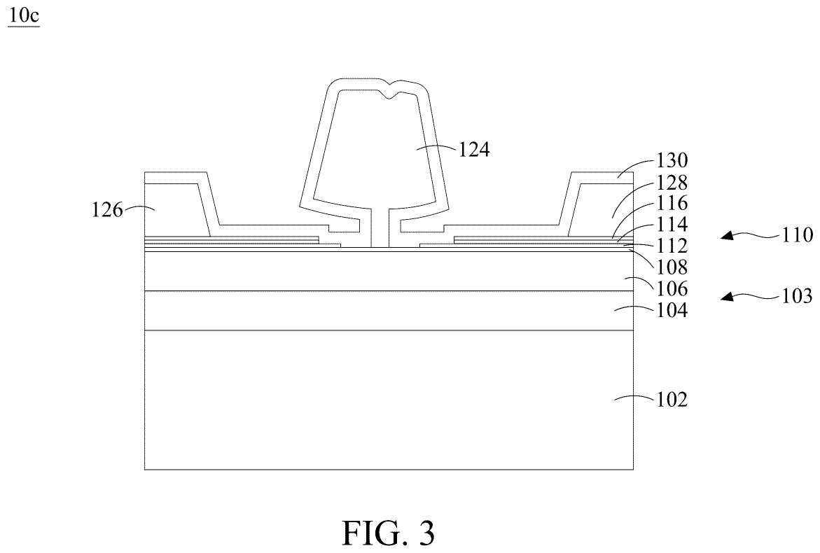

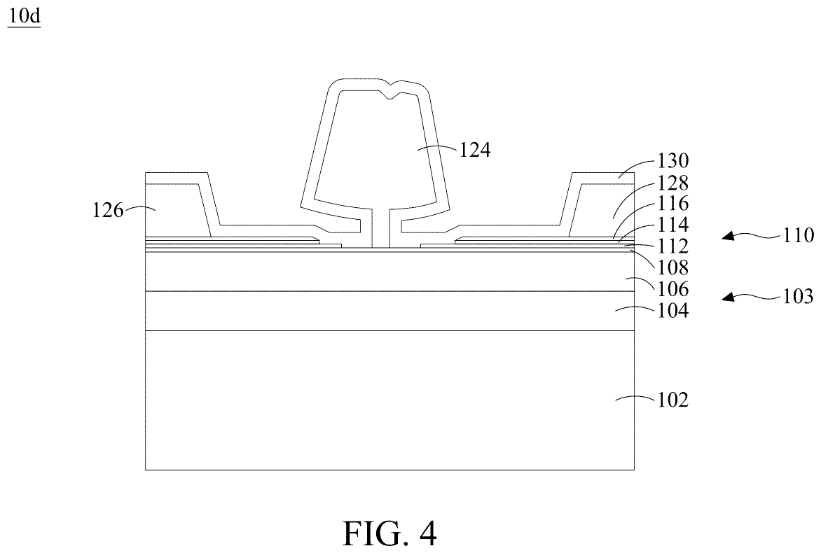

Many variations and/or modifications may be made to the embodiments of the disclosure. FIGS. 3 and 4 are cross-sectional representations of semiconductor structure 10c and 10d in accordance with some embodiments. Some processes or devices are the same as, or similar to, those described in the embodiments above, and therefore the descriptions of these processes and devices are not repeated herein. The difference from the embodiments described above is that, as shown in FIGS. 3 and 4 in accordance with some other embodiments, the shapes of the top cap layer 116 are different from these shapes in the previous embodiments.

The sidewalls of the top cap layer 116 may be substantially vertical to the top surface of the substrate 102, as shown in FIG. 3 in accordance with some embodiments. The top surface of the top cap layer 116 is narrower than the bottom surface of the top cap layer 116, as shown in FIG. 4 in accordance with some embodiments. That is, an inclined sidewall may connect the top surface and the bottom surface of the top cap layer 116. The passivation layer 130 may be formed over the top cap layer 116.

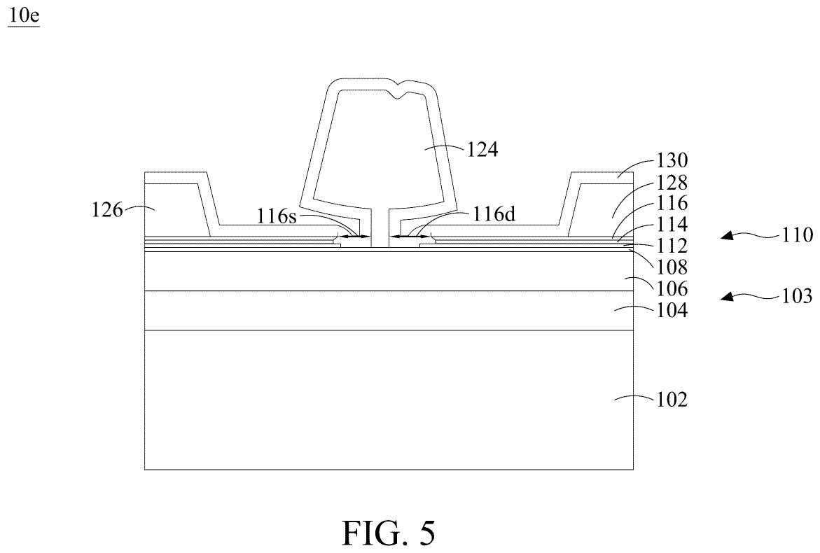

Many variations and/or modifications may be made to the embodiments of the disclosure. FIG. 5 is a cross-sectional representation of a semiconductor structure 10e in accordance with some embodiments. Some processes or devices are the same as, or similar to, those described in the embodiments above, and therefore the descriptions of these processes and devices are not repeated herein. The difference from the embodiments described above is that, as shown in FIG. 5 in accordance with some other embodiments, the gate electrode 124 overlaps the top cap layer 116 adjacent to the drain electrode 128 in the top view.

In some embodiments, the projection of the top cap layer 116 adjacent to the source electrode 126 overlapping the projection of the gate electrode 124 is longer than the projection of the top cap layer 116 adjacent to the drain electrode 128 overlapping the projection of the gate electrode 124.

As mentioned above, in the present disclosure, a HEMT structure and a method of forming a HEMT structure is provided. With a tri-layered cap layer including the protection layer, the etch-stop layer, and the top cap layer, the capacitance may be lowered by the asymmetric top cap layer, and the surface trap may be reduced by the protection layer near the gate electrode. There may be multiple top cap layers and/or etch-stop layer(s), which may increase the breakdown voltage. The shape of the top cap layer may be different. The gate electrode may overlap the top cap layer or be separated from the top cap layer adjacent to the drain electrode in the top view.

It should be noted that although some of the benefits and effects are described in the embodiments above, not every embodiment needs to achieve all the benefits and effects.

The foregoing outlines features of several embodiments so that those skilled in the art may better understand the aspects of the present disclosure. The features of the embodiments mentioned above may be mixed, recombined or restructured to construct another embodiment of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a semiconductor stack disposed on the substrate;
a cap layer disposed on the semiconductor stack and comprising:
an intrinsic cap layer;
an etch-stop layer;
an n-type cap layer; and
an opening through the cap layer;
a source electrode and a drain electrode disposed on the semiconductor stack; and
a gate disposed in the opening and between the source electrode and the drain electrode,
wherein a first distance between the gate and a first portion of the n-type cap layer adjacent to the drain electrode is greater than a second distance between the gate and a second portion of the n-type cap layer adjacent to the source electrode.

2. The semiconductor device as claimed in claim 1, wherein a ratio of the first distance to the second distance is in a range of about 1.2 to about 8.

3. The semiconductor device as claimed in claim 1, wherein a ratio of the first distance to a width of the gate is in a range of about 0.05 to about 4.

4. The semiconductor device as claimed in claim 1, wherein a ratio of the second distance to a width of the gate is in a range of about 0.05 to about 1.5.

5. The semiconductor device as claimed in claim 1, wherein a top surface of the n-type cap layer is wider than a bottom surface of the n-type cap layer.

6. The semiconductor device as claimed in claim 1, wherein a projection of the n-type cap layer adjacent to the source electrode overlaps a projection of the gate in a top view, and the projection of the n-type cap layer adjacent to the drain electrode is separated from the projection of the gate in a top view.

7. The semiconductor device as claimed in claim 1, wherein a projection of the n-type cap layer adjacent to the source electrode overlapping a projection of the gate is longer than a projection of the n-type cap layer adjacent to the drain electrode overlapping a projection of the gate in a top view.

8. The semiconductor device as claimed in claim 1, wherein a distance from the gate to the drain electrode is greater than a distance from the gate to the source electrode.

9. The semiconductor device as claimed in claim 1, wherein a projection of the n-type cap layer adjacent to the source electrode is separated from a projection of the gate in a top view, and the projection of the n-type cap layer adjacent to the drain electrode is separated from the projection of the gate in a top view.

10. The semiconductor device as claimed in claim 1, wherein the intrinsic cap layer comprises GaAs, the etch-stop layer comprises AlAs, and the n-type cap layer comprises GaAs.

11. The semiconductor device as claimed in claim 1, wherein a width of the opening through the intrinsic cap layer is narrower than a width of the opening through the n-type cap layer.

12. A semiconductor device, comprising:
a substrate;
a semiconductor stack disposed on the substrate;
a cap layer disposed on the semiconductor stack and having a top opening and a bottom opening, wherein the bottom opening overlaps the top opening;
a source electrode and a drain electrode disposed on the semiconductor stack; and
a gate disposed in the top opening and the bottom opening, between the source electrode and the drain electrode, and spaced apart from the cap layer,
wherein a first distance between the gate and the cap layer on a drain-side in the top opening is greater than a second distance between the gate and the cap layer on a source-side in the top opening, and a third distance between the gate and the cap layer on the drain-side in the bottom opening is substantially equal to a fourth distance between the gate and the cap layer on the source-side in the bottom opening.

13. The semiconductor device as claimed in claim 12, wherein the cap layer comprises:
a protection layer;
an etch-stop layer disposed on the protection layer; and
an top cap layer disposed on the etch-stop layer.

14. The semiconductor device as claimed in claim 13, further comprising:
a second etch-stop layer disposed on the top cap layer; and
a second top layer disposed on the second etch-stop layer.

15. The semiconductor device as claimed in claim 13, wherein a sidewall of the top cap layer is substantially vertical to the top surface of the substrate.

16. The semiconductor device as claimed in claim 13, wherein a top surface of the top cap layer is narrower than a bottom surface of the top cap layer.

17. The semiconductor device as claimed in claim 13, wherein the etch-stop layer is n-type doped.

18. The semiconductor device as claimed in claim 12, further comprising:
a passivation layer disposed on the gate, in the bottom opening and the top opening.

19. The semiconductor device as claimed in claim 12, wherein the gate comprises a bottom portion disposed in the bottom opening and a top portion disposed on the bottom portion, wherein the top portion of the gate is asymmetric according to the bottom portion.

20. The semiconductor device as claimed in claim 12, wherein a projection of the gate covers the bottom opening in a top view.
